(19) United States
(12) Patent Application Publication
(10) Pub. No.: US 2022/0293848 A1
(43) Pub. Date: Sep. 15, 2022

(54) PIEZOELECTRIC SENSOR

(71) Applicant: SONY GROUP CORPORATION, Tokyo (JP)

(72) Inventor: Kazuhito SHIMODA, Tokyo (JP)

(73) Assignee: SONY GROUP CORPORATION, Tokyo (JP)

(21) Appl. No.: 17/639,685

(22) PCT Filed: Jul. 9, 2020
(86) PCT No.: PCT/JP2020/026815

§ 371 Date: Mar. 2, 2022

(30) Foreign Application Priority Data
Sep. 9, 2019 (JP) 2019-163670

(51) Int. Cl. H01L 41/113; G01H 11/08; H01L 41/053; H01L 41/187

(52) U.S. Cl. CPC H01L 41/1132; G01H 11/08; H01L 41/0533; H01L 41/187; H01L 41/1876

(57) ABSTRACT

A piezoelectric sensor is provided that includes a piezoelectric film that is arranged on a surface of a flexible base material between a first electrode and a second electrode, and a protective film that is coated onto the first electrode, the second electrode, and the piezoelectric film, the piezoelectric films included in a plurality of the piezoelectric films being connected in series through the first electrode and the second electrode, the flexible base material being bent such that the piezoelectric films included in the plurality of the piezoelectric films are arranged in a layered formation.

### TECHNICAL FIELD

The present technology relates to a piezoelectric sensor.

### BACKGROUND ART

Piezoelectric sensors have various applications. Piezoelectric sensors are used to detect a weak oscillation, which is an example of such applications. It is necessary that a piezoelectric sensor have a high detection sensitivity in order for the piezoelectric sensor to detect a relatively weak oscillation. Since the output voltage of a single piezoelectric film is known to be proportional to the product of a piezoelectric constant and a thickness of the film, making the piezoelectric film thicker is one of the methods for obtaining a higher detection sensitivity with a single piezoelectric film. However, the crystallinity of a piezoelectric film will be reduced if the film is made thicker. Consequently, the high detection sensitivity is not effectively obtained. Thus, it is necessary that piezoelectric films included in a plurality of piezoelectric films be connected in series in order to obtain a high detection sensitivity.

Patent Literature 1 discloses a piezoelectric sensor that includes a polymeric piezoelectric film and electrodes respectively formed on two sides of the polymeric piezoelectric film, the polymeric piezoelectric film with the formed electrodes being folded back to form a unit, the units of a plurality of the units being connected in series to obtain the piezoelectric sensor having a high detection sensitivity.

### CITATION LIST

### Patent Literature

Patent Literature 1: Japanese Patent Application Laid-open No. 2019-007749

### DISCLOSURE OF INVENTION

### Technical Problem

However, there is a need for a large number of parts to be produced and for a large number of processes of connecting and assembling the parts, in order to obtain the piezoelectric sensor disclosed in Patent Literature 1. This results in high production costs.

Thus, it is an object of the present technology to provide a piezoelectric sensor that has a high detection sensitivity and for which production costs are low.

### Solution to Problem

In order to achieve the object described above, the present technology provides a piezoelectric sensor that includes

a piezoelectric film that is arranged on a surface of a flexible base material between a first electrode and a second electrode, and

a protective film that is coated onto the first electrode, the second electrode, and the piezoelectric film, the piezoelectric films included in a plurality of the piezoelectric films being connected in series through the first electrode and the second electrode, the flexible base material being bent such that the piezoelectric films included in the plurality of the piezoelectric films are arranged in a layered formation.

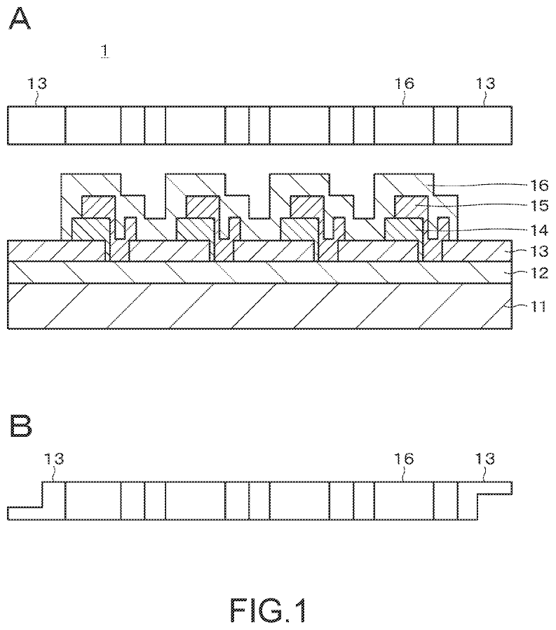

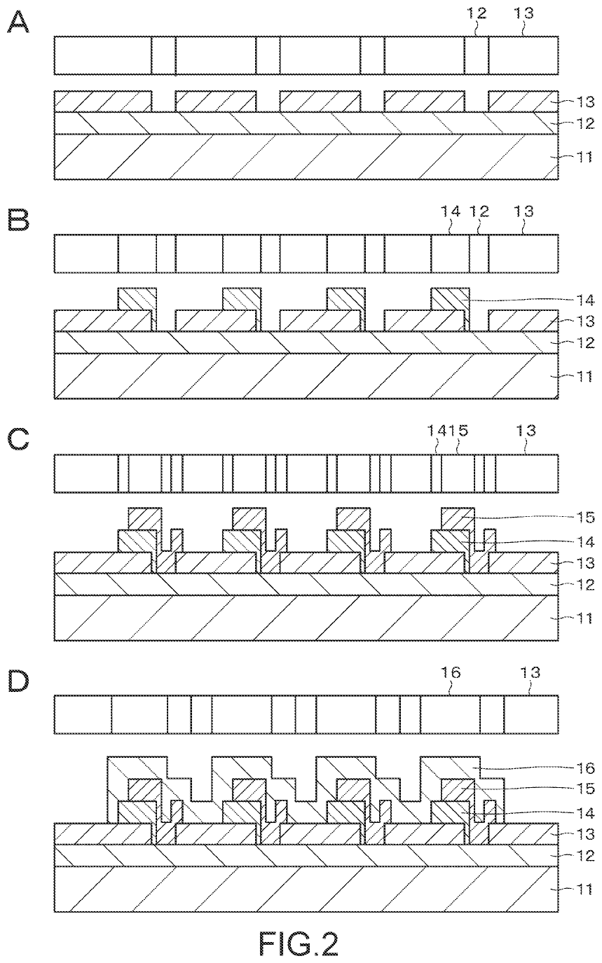

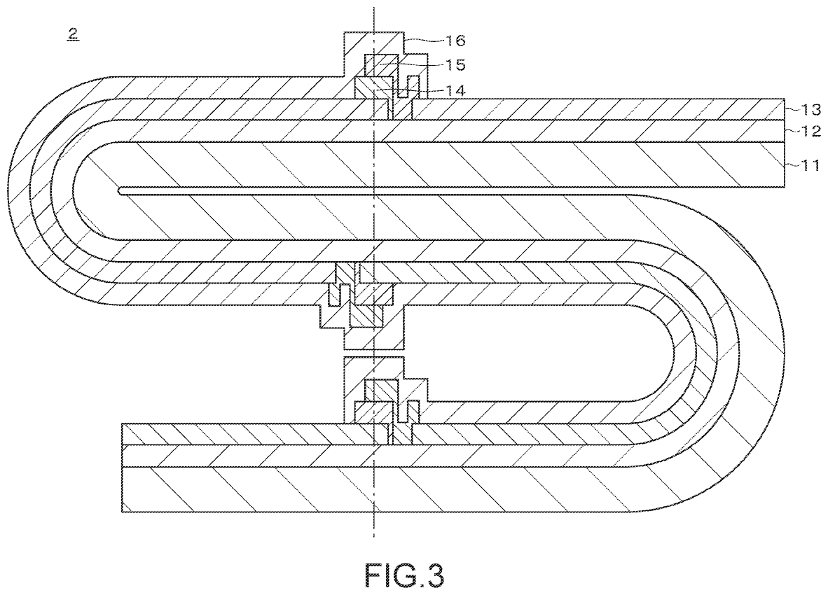

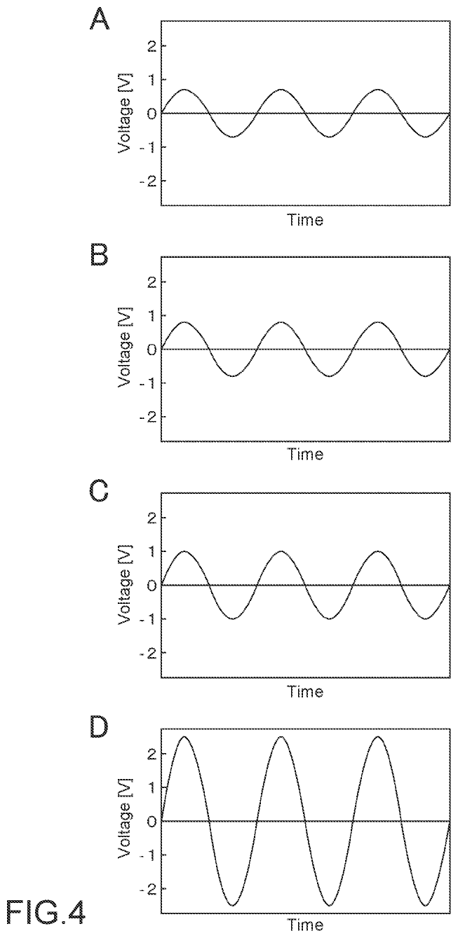

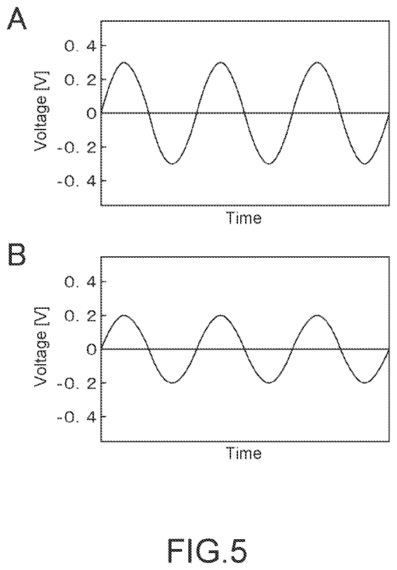

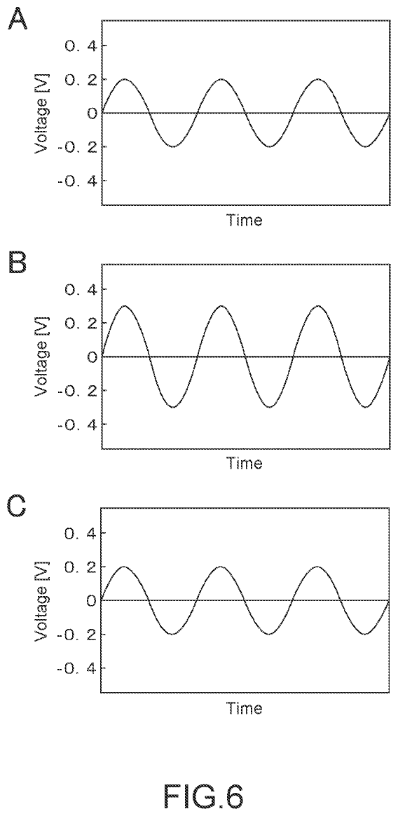

### BRIEF DESCRIPTION OF DRAWINGS

[FIG. 1] A of FIG. 1 illustrates a plan view and a central cross-sectional view of a piezoelectric sensor according to an embodiment, and B of FIG. 1 is a plan view of the piezoelectric sensor of which two ends have been processed.

[FIG. 2] A to D of FIG. 2 are diagrams illustrating a process of producing the piezoelectric sensor according to the embodiment.

[FIG. 3] FIG. 3 is a cross-sectional view of a piezoelectric sensor of an example.

[FIG. 4] A to D of FIG. 4 are diagrams schematically illustrating results of the example.

[FIG. 5] A and B of FIG. 5 are diagrams schematically illustrating results of a first comparative example.

[FIG. 6] A to C of FIG. 6 are diagrams schematically illustrating results of a second comparative example.

### MODE(S) FOR CARRYING OUT THE INVENTION

Embodiments and the like of the present technology will now be described below with reference to the drawings. Note that the description is made in the following order.

### EMBODIMENT

### <Modifications>

The embodiments and the like described below are favorable specific examples of the present technology, and contents of the present technology are not limited to these embodiments and the like.

### 1. Embodiment

“Structure”

A piezoelectric sensor 1 of an embodiment can be bent. In order to obtain the bendable piezoelectric sensor 1, a flexible base material is used as a substrate of the piezoelectric sensor 1. The flexible base material is, for example, a metallic foil 11. It is favorable that a material of the metallic foil 11 be a material such as Alloy 42 or Kovar that has a coefficient of linear expansion that is as close to the coefficient of linear expansion of a piezoelectric film 14 described later as possible, but the material of the metallic foil 11 may be another metallic material. The metallic foil 11 has a thickness of greater than or equal to 10 μm and less than or equal to 100 μm. Considering that resistance to bending is improved due to a reduction in edge stress, it is favorable that the metallic foil 11 have a thickness of greater than or equal to 10 μm and less than or not equal to 50 μm.

The metallic foil 11 is electroconductive, and a short circuit may be caused if an element of, for example, the piezoelectric sensor 1 is formed using the metallic foil 11 with no change. Thus, the surface of the metallic foil 11 is coated with an insulation film 12, and this results in electrically insulating the surface of the metallic foil 11. Examples of the insulation film 12 include an oxide film such as SiO₂ or Al₂O₃, a nitride film such as Si₃N₄, and an oxynitride film such as SiON. When the metallic foil 11 is used as the flexible base material, this has the advantage of enabling a high-temperature condition to be used in the process of producing a piezoelectric film.

A of FIG. 1 illustrates an example of the piezoelectric sensor 1 according to the embodiment. As illustrated in A of FIG. 1, one of surfaces of the metallic foil 11 is coated with the insulation film 12, and a surface of the insulation film 12 is coated with a first electrode 13 repeatedly with specified spacing. It is favorable that a material that favors crystallization of the piezoelectric film 14 be used as a material of the first electrode 13, and examples of the material of the first electrode 13 include Al, Cu, Ag, Au, Pt, Mo, and Ir. The thickness of the first electrode 13 is favorably greater than or equal to 50 nm, and is more favorably from about 100 nm to about 200 nm.

A portion of the first electrode 13 is coated with the piezoelectric film 14. Examples of a material of the piezoelectric film 14 include lead zirconate titanate (PZT), AlN, ZnO, metal-doped PZT, metal-doped AlN, and metal-doped ZnO, and it is favorable that a piezoelectric constant be increased by a c-axis orientation being further increased. It is favorable that the pattern of the piezoelectric film 14 be a square with about 1 mm to about 10 mm on a side in order to increase mass productivity, and it is favorable that the piezoelectric film 14 have a thickness of from about 100 nm to about 10 μm. It is favorable that a buffer layer (not illustrated) be formed between the first electrode 13 and the piezoelectric film 14 in order to improve the crystallinity of the piezoelectric film 14. Examples of the buffer layer include SrRuO₃, ZrO₂, and AlN.

The arrangement of the piezoelectric film is controlled by the length and spacing of the first electrode 13. A portion of the surface of the first electrode 13 is coated with the piezoelectric film 14. A second electrode 15 is coated onto a region from a surface of the piezoelectric film 14 to a portion of a surface of the first electrode 13 being adjacent to the first electrode 13 coated with the piezoelectric film 14. The piezoelectric film 14 of A of FIG. 1 is also coated onto one of two end surfaces of the first electrode 13. When connection is established such that two primary surfaces of the piezoelectric film 14 are situated between the first electrode 13 and the second electrode 15 and when the second electrode 15 is connected to another adjacent first electrode 13 (on the right in A of FIG. 1), as illustrated in A of FIG. 1, this results in a series connection. A of FIG. 1 illustrates four in series (4S) since four piezoelectric films 14 are connected in series.

A protective film 16 is coated as a top layer of the piezoelectric sensor 1. Examples of a material of the protective film 16 include an oxide film of, for example, SiO₂ or Al₂O₃, a nitride film of, for example, Si₃N₄, and an oxynitride film of, for example, SiON. The protective film 16 serves to perform insulation from the outside, and, for example, the protective film 16 serves to insulate the piezoelectric film 14 from another piezoelectric film 14 when the piezoelectric films 14 are arranged in a layered formation. The protective film 16 is not coated onto portions of the first electrodes 13 respectively situated at two ends of the piezoelectric sensor 1. The first electrodes 13 respectively situated at the two ends of the piezoelectric sensor 1 are used as extraction electrodes for a detection signal. In order to enable the first electrode 13 situated at each of the two ends of the piezoelectric sensor 1 to be easily used as an extraction electrode, a portion of the first electrode 13 situated at each of the two ends of the piezoelectric sensor 1 may be cut out by, for example, laser processing and may be processed to be thin like a lead.

“Production Method”

A method for producing the piezoelectric sensor 1 of the embodiment is described. First, the metallic foil 11 is prepared as a flexible base material. The insulation film 12 is formed on the entirety of a primary surface of the metallic foil 11. The insulation film 12 is made of an insulation material such as an oxide film, a nitride film, or an oxynitride film. Then, the first electrode 13 is formed at regular intervals, as illustrated in A of FIG. 2. The first electrodes 13 being adjacent to each other are equally spaced. The first electrode 13 is made of a metallic material, as described above.

Next, the piezoelectric film 14 is formed on the surfaces of the first electrode 13 and the insulation film 12, as illustrated in B of FIG. 2. The piezoelectric film 14 is coated onto a portion of a primary surface of the first electrode 13 and onto one of the two end surfaces of the first electrode 13. Then, the second electrode 15 is formed on the surfaces of the piezoelectric film 14, the insulation film 12, and the first electrode 13, as illustrated in C of FIG. 2. The second electrode 15 serves to electrically connect the piezoelectric film 14 and the adjacent first electrode 13. The material described above is used as the material of the piezoelectric film 14, and a metallic material is used for the second electrode 15, as in the case of the first electrode 13.

Finally, the protective film 16 is formed on the entirety of the surface from which portions of the first electrodes 13 respectively being situated at two ends have been excluded, as illustrated in D of FIG. 2. The material of the protective film 16 is similar to the material of the insulation film 12 coated onto the metallic foil. The protective film 16 serves to perform electrical insulation from the outside. All of the films described above are formed by sputtering.

### EXAMPLES

The present technology is specifically described below on the basis of examples in which a test is conducted using the piezoelectric sensor produced as described above, the test including giving an oscillation to the piezoelectric sensor in a state in which pressure is being applied to the piezoelectric sensor. Note that the present technology is not limited to the examples described below.

### Example

As illustrated in FIG. 3, a piezoelectric sensor 2 that includes three piezoelectric films 14 was prepared, and the piezoelectric sensor 2 was bent at a portion that does not include the piezoelectric film 14 (a portion that is situated between the piezoelectric film 14 and another piezoelectric film 14 being adjacent to the piezoelectric film 14, and includes the first electrode 13) such that the piezoelectric films 14 were arranged in a layered formation at substantially the same position in a dot-dash line, as illustrated in FIG. 3. The three piezoelectric films 14 were connected in series (three in series). A weight was placed above the piezoelectric films 14 being arranged in a layered formation at substantially the same position to apply a force of 1200 N to the piezoelectric films 14, and, in a state in which the force was being applied, a sinusoidal oscillation was given to the piezoelectric films 14 from above the weight using an AE sensor to measure a waveform of voltage generated by the piezoelectric sensor 2. The frequency of the sinusoidal oscillation was 270 kHz. The distance between the AE sensor and the piezoelectric sensor 2 being situated across the weight from each other was about 10 cm. Likewise, pressure was applied to the three piezoelectric films 14 being arranged in a layered formation, and, in a state in which the pressure was being applied, the sinusoidal oscillation was given to the three piezoelectric films 14 to measure a waveform of an individual voltage output from each of the piezoelectric films 14.

A to C of FIG. 4 schematically illustrate results of individually measuring waveforms of voltages respectively output from the piezoelectric films not being arranged in a layered formation. The individual voltages respectively output from the piezoelectric films not being arranged in a layered formation were 700 mV (A of FIG. 4), 800 mV (B of FIG. 4), and 1000 mV (C of FIG. 4), respectively. Voltage output from the piezoelectric films being arranged in a layered formation at substantially the same position, as illustrated in FIG. 3, was 2500 mV, as illustrated in D of FIG. 4.

### First Comparative Example

A piezoelectric sensor in which two piezoelectric films connected in series were placed side by side was prepared. A force was applied to the two piezoelectric films 14 using a weight, and, in a state in which the force was being applied, a sinusoidal oscillation similar to the sinusoidal oscillation given in the example was given to the two piezoelectric films 14 to measure a waveform of a voltage generated by the piezoelectric sensor. Further, a force was applied to the two piezoelectric films being placed side by side, and, in a state in which the force was being applied, the sinusoidal oscillation was given to the two piezoelectric films to measure a waveform of an individual voltage output from each of the piezoelectric films 14, as in the case of the example.

A and B of FIG. 5 schematically illustrate results of individually measuring waveforms of voltages respectively output from the piezoelectric films of a first comparative example. Values of the individual voltages respectively output from the piezoelectric films were 300 mV (A of FIG. 5) and 200 mV (B of FIG. 5), respectively, and stable voltage waveforms were obtained. Unstable voltage waveforms were obtained when pressure was applied to the two piezoelectric films being placed side by side using a weight, and a constant voltage value was not obtained (not illustrated).

### Second Comparative Example

A piezoelectric sensor in which two piezoelectric films 14 connected in parallel were arranged in a layered formation at substantially the same position, as in the case of the example, was prepared. As in the case of the example, a force was applied to the two piezoelectric films 14, and, in a state in which the force was being applied, a sinusoidal oscillation was given to the two piezoelectric films 14 to measure a waveform of a voltage generated by the piezoelectric sensor. Further, pressure was applied to the two piezoelectric films 14 not being connected in parallel and being arranged in a layered formation at substantially the same position, and, in a state in which the pressure was being applied, the sinusoidal oscillation was given to the two piezoelectric films to measure a waveform of an individual voltage output from each of the piezoelectric films 14, as in the case of the example.

A and B of FIG. 6 schematically illustrate results of individually measuring waveforms of voltages respectively output from the piezoelectric films 14 of a second comparative example. Values of the individual voltages respectively output from the piezoelectric films 14 were 200 mV (A of FIG. 6) and 300 mV (B of FIG. 6), respectively. When the two piezoelectric films 14 connected in parallel were arranged in a layered formation at substantially the same position, a voltage value was 200 mV, as illustrated in C of FIG. 6.

The voltage value of the piezoelectric sensor 2 of the example was substantially equal to the sum of the voltage values of the respective piezoelectric films 14, whereas the voltage value of the piezoelectric sensor of the second comparative example was different from the sum of the voltage values of the respective piezoelectric films 14. Further, in the first comparative example, the voltage value was not stable. It can be said that the voltage of the piezoelectric sensor 2 of the example exhibits a waveform more stable than the waveform in the first comparative example, and the piezoelectric sensor 2 of the example has a higher detection sensitivity than the second comparative example. Thus, in the present technology, signal generators are situated at the same position with respect to a measurement-target object due to folding back. This makes it possible to reduce variation in output signal while enhancing an output signal.

The piezoelectric sensor 1 and the piezoelectric sensor 2 are each completed by performing about five film-formation processes without making the piezoelectric film 14 thicker. In the piezoelectric sensor 2, the piezoelectric films 14 connected in series are arranged in a layered formation due to the piezoelectric sensor 2 being bent. Accordingly, the present technology makes it possible to arrange piezoelectric films included in a plurality of piezoelectric films in a layered formation by performing a smallest number of film-formation processes without forcibly making the piezoelectric film thicker. This results in an easier production process and in lower costs.

The embodiment described above makes it possible to reduce the number of parts and the number of processes, and thus to provide an inexpensive piezoelectric sensor having a high detection sensitivity. Note that contents of the present technology are not to be construed as being limited due to the effects illustrated herein.

### 2. Modifications

The embodiment of the present technology has been specifically described above. However, contents of the present technology are not limited to the embodiment described above, and various modifications based on technical ideas of the present technology may be made thereto.

In the embodiment described above, four piezoelectric films are connected in series. However, more or less than four piezoelectric films may be connected in series. In the piezoelectric sensor 2 of the example, three piezoelectric films are arranged in a layered formation. However, two piezoelectric films or four or more piezoelectric films may be arranged in a layered formation.

When the first electrode 13 is used as an extraction electrode, the extraction electrodes situated at two ends of the piezoelectric sensor 2 of the example are oriented opposite to each other. However, if the piezoelectric sensor 2 includes an even number (2, 4, 6, . . . ) of piezoelectric films 14, the extraction electrodes can be arranged to be oriented in the same direction for extraction by the piezoelectric sensor 2 being bent at a portion that includes an odd-numbered piezoelectric film 14 (2-1, 4-1, 6-1, . . . ). Further, if the piezoelectric sensor 2 includes an odd number of piezoelectric films 14 such as three piezoelectric films 14, as in the case of the example, the extraction electrodes can be arranged to be oriented in the same direction for extraction by a portion that is situated at one of the two ends of the piezoelectric sensor 2 and does not include the piezoelectric film 14 being made longer, and by one more portion at which the piezoelectric sensor 2 is to be bent being created such that there are an odd number of portions to be bent.

Further, the flexible base material may be a polyimide resin having a thickness of greater than or equal to 10 μm and less than or equal to 200 μm. In this case, there is no need to form the insulation film 12 on a surface of the polyimide resin, since the polyimide resin itself has insulation properties. The polyimide resin is suitable when a high-temperature condition is not imposed on the process of producing the piezoelectric film 14.

Furthermore, the example in which sputtering is used as the method for forming a film in the piezoelectric sensor 1 has been described above. However, a film is formed by application, vapor deposition, or any other method.

Further, the present technology may also take the following configurations.

(1) A piezoelectric sensor, including:

a piezoelectric film that is arranged on a surface of a flexible base material between a first electrode and a second electrode; and

a protective film that is coated onto the first electrode, the second electrode, and the piezoelectric film, the piezoelectric films included in a plurality of the piezoelectric films being connected in series through the first electrode and the second electrode, the flexible base material being bent such that the piezoelectric films included in the plurality of the piezoelectric films are arranged in a layered formation.

(2) The piezoelectric sensor according to (1), in which

the first electrode is coated onto the surface of the flexible base material repeatedly with spacing,

the piezoelectric film is coated onto a portion of the first electrode, and

the second electrode is coated onto the first electrode being adjacent to the first electrode coated with the piezoelectric film, and onto the piezoelectric film.

(3) The piezoelectric sensor according to (1) or (2), in which

a portion at which the flexible base material is bent is a portion corresponding to a portion, in the piezoelectric sensor, that is situated between the piezoelectric film and another piezoelectric film adjacent to the piezoelectric film and includes the first electrode.

(4) The piezoelectric sensor according to any one of (1) to (3), in which

when there are an odd number of the piezoelectric films, a portion that is situated on one of two ends of the piezoelectric sensor and is not coated with the piezoelectric film is bent, and extraction electrodes are arranged to be oriented in the same direction.

(5) The piezoelectric sensor according to any one of (1) to (4), in which

a material of the piezoelectric film is one of PZT, AlN, ZnO, metal-doped PZT, metal-doped AlN, and metal-doped ZnO.

(6) The piezoelectric sensor according to any one of (1) to (5), in which

the piezoelectric film has a thickness of from 100 nm to 10 μm.

(7) The piezoelectric sensor according to any one of (1) to (6), in which

the flexible base material has a thickness of greater than or equal to 10 μm and less than or equal to 100 μm, and is a metallic foil that has a surface on which an insulation film is formed.

(8) The piezoelectric sensor according to any one of (1) to (6), in which

the flexible base material is a polyimide resin that has a thickness of greater than or equal to 10 μm and less than or equal to 200 μm.

(9) The piezoelectric sensor according to any one of (1) to (8), in which

the protective film is one of an oxide film, a nitride film, and an oxynitride film.

### REFERENCE SIGNS LIST

1, 2 piezoelectric sensor
11 metallic foil
12 insulation film
13 first electrode
14 piezoelectric film
15 second electrode
16 protective film

What is claimed is:

1. A piezoelectric sensor, comprising:
a piezoelectric film that is arranged on a surface of a flexible base material between a first electrode and a second electrode; and
a protective film that is coated onto the first electrode, the second electrode, and the piezoelectric film, the piezoelectric films included in a plurality of the piezoelectric films being connected in series through the first electrode and the second electrode, the flexible base material being bent such that the piezoelectric films included in the plurality of the piezoelectric films are arranged in a layered formation.

2. The piezoelectric sensor according to claim 1, wherein
the first electrode is coated onto the surface of the flexible base material repeatedly with spacing,
the piezoelectric film is coated onto a portion of the first electrode, and
the second electrode is coated onto the first electrode being adjacent to the first electrode coated with the piezoelectric film, and onto the piezoelectric film.

3. The piezoelectric sensor according to claim 1, wherein
a portion at which the flexible base material is bent is a portion corresponding to a portion, in the piezoelectric sensor, that is situated between the piezoelectric film and another piezoelectric film adjacent to the piezoelectric film and includes the first electrode.

4. The piezoelectric sensor according to claim 1, wherein
when there are an odd number of the piezoelectric films, a portion that is situated on one of two ends of the piezoelectric sensor and is not coated with the piezoelectric film is bent, and extraction electrodes are arranged to be oriented in the same direction.

5. The piezoelectric sensor according to claim 1, wherein
a material of the piezoelectric film is one of PZT, AlN, ZnO, metal-doped PZT, metal-doped AlN, and metal-doped ZnO.

6. The piezoelectric sensor according to claim 1, wherein
the piezoelectric film has a thickness of from 100 nm to 10 μm.

7. The piezoelectric sensor according to claim 1, wherein
the flexible base material has a thickness of greater than or equal to 10 μm and less than or equal to 100 μm, and is a metallic foil that has a surface on which an insulation film is formed.

8. The piezoelectric sensor according to claim 1, wherein
the flexible base material is a polyimide resin that has a thickness of greater than or equal to 10 μm and less than or equal to 200 μm.

9. The piezoelectric sensor according to claim 1, wherein
the protective film is one of an oxide film, a nitride film, and an oxynitride film.
